(19) United States
(12) Patent Application Publication
(10) Pub. No.: US 2026/0075904 A1
(43) Pub. Date: Mar. 12, 2026

(54) POWER SEMICONDUCTOR DEVICES INCLUDING DEEP SHIELDING REGIONS

(71) Applicant: Wolfspeed, Inc., Durham, NC (US)

(72) Inventors: Naeem Islam, Morrisville, NC (US); Madankumar Sampath, Durham, NC (US); Woongsun Kim, Cary, NC (US); Sei-Hyung Ryu, Cary, NC (US)

(21) Appl. No.: 18/830,731

(22) Filed: Sep. 11, 2024

(51) Int. Cl. H01L 29/167; H01L 29/16; H01L 29/66; H01L 29/78

(52) U.S. Cl. CPC H10D 62/834; H10D 30/0297; H10D 30/665; H10D 30/668; H10D 62/8325; H10D 84/146

(57) ABSTRACT

A power semiconductor device includes a semiconductor structure having a first side, a second side, and a drift region of a first conductivity type therebetween, and implanted regions of a second conductivity type in the semiconductor structure adjacent the first side of the semiconductor structure. The implanted regions include first portions of a first material and second portions of a second material, with the second portions positioned between the first portions and the second side. The second material has an atomic weight that is lighter than that of the first material. Related fabrication methods are also discussed.

### FIELD

The present invention relates to semiconductor devices and, more particularly, to power semiconductor devices.

### BACKGROUND

Power semiconductor devices refer to devices that include one or more “power” semiconductor die that are designed to carry large currents (e.g., tens or hundreds of Amps) and/or that are capable of blocking high voltages (e.g., hundreds, thousand or tens of thousands of volts). A wide variety of power semiconductor devices are known in the art including, for example, power Metal Insulator Semiconductor Field Effect Transistors (“MISFETs,” including Metal Oxide Semiconductor FETs (“MOSFETs”)), bipolar junction transistors (“BJTs”), Insulated Gate Bipolar Transistors (“IGBT”), Junction Barrier Schottky diodes, Gate Turn-Off Transistors (“GTO”), MOS-controlled thyristors, and various other devices. These power semiconductor devices are generally fabricated from wide bandgap semiconductor materials, for example, silicon carbide (“SiC”) or Group III nitride (e.g., gallium nitride (“GaN”))-based semiconductor materials. Herein, a wide bandgap semiconductor material refers to a semiconductor material having a bandgap greater than about 1.40 eV, for example, greater than about 2 eV.

A conventional power semiconductor device typically has a semiconductor substrate having a first conductivity type (e.g., an n-type substrate) on which an epitaxial layer structure having the first conductivity type (e.g., n-type) is formed. A portion of this epitaxial layer structure (which may comprise one or more separate layers) functions as a drift layer or drift region of the power semiconductor device. The device typically includes an “active region,” which includes one or more “unit cell” structures that have a junction, for example, a p-n junction. The active region may be formed on and/or in the drift region. The active region acts as a main junction for blocking voltage in the reverse bias direction and providing current flow in the forward bias direction. The power semiconductor device may also have an edge termination in a termination region that is adjacent the active region. One or more power semiconductor devices may be formed on the substrate, and each power semiconductor device will typically have its own edge termination. After the substrate is fully processed, the resultant structure may be diced to separate the individual edge-terminated power semiconductor devices.

Power semiconductor devices may have a unit cell configuration in which a large number of individual unit cell structures of the active region are electrically connected (e.g., in parallel) to function as a single power semiconductor device. In high power applications, such a power semiconductor device may include thousands or tens of thousands of unit cells implemented in a single chip or “die.” A die or chip may include a small block of semiconducting material or other substrate in which electronic circuit elements are fabricated. For example, a plurality of individual power semiconductor devices may be formed on a relatively large semiconductor substrate (e.g., by growing epitaxial layers there on doping selected regions with dopants, forming insulation and metal layers thereon, etc.) and the completed structure may then be cut (e.g., by a sawing or dicing operation) into a plurality of individual die, each of which is a power semiconductor device.

Power semiconductor devices can have a lateral structure or a vertical structure. In a device having a lateral structure, the terminals of the device (e.g., the drain, gate and source terminals for a power MOSFET device) are on the same major surface (e.g., top or bottom) of a semiconductor structure. In contrast, in a device having a vertical structure, at least one terminal is provided on each major surface of the semiconductor structure (e.g., in a vertical MOSFET device, the source may be on the top surface (or first side) of the semiconductor structure and the drain may be on the bottom surface (or second side) of the semiconductor layer structure). The semiconductor structure may or may not include an underlying substrate. Herein, the term “semiconductor structure” refers to a structure that includes one or more semiconductor layers, including semiconductor substrates and/or semiconductor epitaxial layers.

Vertical power semiconductor devices, such as MOSFET or IGBT devices, can have a standard gate electrode design in which the gate electrode of the transistor is formed on top of the semiconductor structure or, alternatively, may have the gate electrode buried in a trench within the semiconductor structure. Devices having buried gate electrodes are typically referred to as gate trench devices. With the standard gate electrode design, the channel region of each unit cell transistor is at least partially horizontally disposed underneath the gate electrode. In contrast, in the gate trench design, the channel is vertically disposed. Gate trench devices may provide enhanced performance, but typically require more complex manufacturing processes.

Power semiconductor devices are designed to block (in the forward or reverse blocking state) or pass (in the forward operating state) large voltages and/or currents. For example, in the blocking state, a power semiconductor device may be designed to sustain hundreds or thousands of volts of electric potential. As the applied voltage approaches or passes the voltage level that the device is designed to block, non-trivial levels of current (referred to as leakage current) may begin to flow through the power semiconductor device. The blocking capability of the device may be a function of, among other things, the doping density/concentration and thickness of the drift region. Leakage currents may also arise for other reasons, such as failure of the edge termination and/or the primary junction of the device. If the voltage applied to the device is increased beyond the breakdown voltage to a critical level, the increasing electric field may result in an uncontrollable and undesirable runaway generation of charge carriers within the semiconductor device, leading to a condition known as avalanche breakdown.

Also, the relatively thin gate oxide (or other gate insulating layer) that separates the gate electrode from the semiconductor structure can degrade when the gate insulating layer is subjected to high electric field levels, during either on-state (conducting) or off-state (blocking) operation. This degradation of the gate insulating layer may ultimately lead to breakdown of the gate insulating layer, at which point the gate electrode may short circuit to the semiconductor structure, which can destroy the device.

### SUMMARY

According to some embodiments, a power semiconductor device includes a semiconductor structure with a first side, a second side, and a drift region of a first conductivity type therebetween. The device also includes implanted regions of a second conductivity type within the semiconductor structure, adjacent to the first side. The implanted regions contain a first dopant material and a second dopant material, where the second dopant material is between the first dopant material and the second side of the semiconductor structure. The atomic weight of the second dopant material is lighter than that of the first dopant material.

In some embodiments, the atomic weight of the second dopant material is less than that of aluminum (Al).

In some embodiments, the second dopant material includes at least one of boron (B), beryllium (Be), or magnesium (Mg).

In some embodiments, the power semiconductor device further includes a source contact and a gate on the first side of the semiconductor structure. The gate is in or on a portion of the drift region between the implanted regions, and the implanted regions provide support shielding regions of a transistor that includes the source contact and the gate.

In some embodiments, the power semiconductor device further includes a gate trench having the gate therein, which extends into the portion of the drift region from the first side of the semiconductor structure toward the second side. The support shielding regions are spaced apart from opposing sidewalls of the gate trench and extend toward the second side beyond the bottom surface of the gate trench.

In some embodiments, the power semiconductor device further includes a bottom shielding region of the second conductivity type beneath the bottom surface of the gate trench. The support shielding regions extend toward the second side beyond the bottom shielding region.

In some embodiments, the bottom shielding region includes one of the first dopant material or the second dopant material.

In some embodiments, lateral spacings between the support shielding regions are non-uniform over respective depths thereof.

In some embodiments, surfaces of the drift region containing the implanted regions are recessed relative to at least a portion of the drift region between the implanted regions.

In some embodiments, the power semiconductor device further includes an anode contact on the first side of the semiconductor structure. The anode contact includes a metal that forms a Schottky barrier with the drift region, and the implanted regions provide well regions of a diode that includes the Schottky barrier.

In some embodiments, the drift region includes an active region and an edge termination region located between the active region and a peripheral edge of the semiconductor structure, and the implanted regions provide termination rings that extend into the edge termination region.

In some embodiments, second portions of the implanted regions that include the second dopant material laterally extend towards one another beyond first portions of the implanted regions that include the first dopant material.

In some embodiments, the semiconductor structure includes a silicon carbide substrate and/or one or more silicon carbide epitaxial layers, and the implanted regions further include carbon (C).

According to some embodiments, a power semiconductor device includes a semiconductor structure with a first side, a second side, and a drift region of a first conductivity type therebetween. The device also includes implanted regions including a material of a second conductivity type in the semiconductor structure adjacent to the first side. The atomic weight of the material of the second conductivity type is less than that of aluminum (Al).

In some embodiments, the material of the second conductivity type includes at least one of boron (B), beryllium (Be), or magnesium (Mg).

In some embodiments, lateral spacings between the implanted regions are non-uniform over respective depths thereof.

In some embodiments, the drift region includes silicon carbide (SiC), and the implanted regions further include carbon (C).

In some embodiments, the power semiconductor device further includes a source contact and a gate on the first side of the semiconductor structure. The gate is in or on a portion of the drift region between the implanted regions, and the implanted regions provide support shielding regions of a transistor that includes the source contact and the gate.

In some embodiments, the power semiconductor device further includes a gate trench having the gate therein, which extends into the portion of the drift region from the first side of the semiconductor structure toward the second side. The support shielding regions are spaced apart from opposing sidewalls of the gate trench and extend toward the second side beyond the bottom surface of the gate trench.

In some embodiments, the power semiconductor device further includes an anode contact on the first side of the semiconductor structure. The anode contact includes a metal that forms a Schottky barrier with the drift region, and the implanted regions provide well regions of a diode that includes the Schottky barrier.

In some embodiments, the drift region includes an active region and an edge termination region located between the active region and a peripheral edge of the semiconductor structure, and the implanted regions provide termination rings that extend into the edge termination region.

According to some embodiments, a method of fabricating a power semiconductor device includes providing a semiconductor structure with a drift region of a first conductivity type. The method also includes providing a mask pattern on a surface of the semiconductor structure, where the mask pattern has openings that expose portions of the semiconductor structure. The method further includes implanting a first dopant material of a second conductivity type into the exposed portions of the semiconductor structure to a first depth relative to the surface, and implanting a second dopant material of the second conductivity type into the exposed portions to a second depth relative to the surface. Implanting the first and second dopant materials is performed with a substantially similar implant energy, forming first and second portions of implanted regions within the semiconductor structure, respectively. The second depth is greater than the first depth.

In some embodiments, the atomic weight of the second dopant material is lighter than that of the first dopant material.

In some embodiments, the atomic weight of the second dopant material is less than that of aluminum (Al).

In some embodiments, the second dopant material includes at least one of boron (B), beryllium (Be), or magnesium (Mg).

In some embodiments, the drift region includes silicon carbide (SiC).

In some embodiments, the method further includes performing an implant activation process after implanting the first and second dopant materials. In response to the implant activation process, the second portions of the implanted regions including the second dopant material laterally diffuse toward one another in the drift region.

In some embodiments, implanting the second dopant material is performed using a channeling implantation process.

In some embodiments, implanting the second dopant material includes co-implanting carbon (C) into the portions of the drift region along with the second dopant material.

In some embodiments, the method further includes performing an etching process to recess the portions of the drift region exposed by the openings in the mask prior to implanting the first and second dopant materials.

In some embodiments, the method further includes forming a source contact and a gate on the first side of the semiconductor structure. The gate is in or on a portion of the drift region between the implanted regions, and the implanted regions provide support shielding regions of a transistor that includes the source contact and the gate.

In some embodiments, the method further includes forming a gate trench having the gate therein, which extends into the portion of the drift region from the first side of the semiconductor structure toward the second side. The support shielding regions are spaced apart from opposing sidewalls of the gate trench and extend toward the second side beyond the bottom surface of the gate trench.

In some embodiments, the method further includes forming a bottom shielding region of the second conductivity type beneath the bottom surface of the gate trench. The support shielding regions extend toward the second side beyond the bottom shielding region.

In some embodiments, the bottom shielding region includes one of the first dopant material or the second dopant material.

In some embodiments, the method further includes forming an anode contact on the first side of the semiconductor structure. The anode contact includes a metal that forms a Schottky barrier with the drift region, and the implanted regions provide well regions of a diode that includes the Schottky barrier.

In some embodiments, the drift region includes an active region and an edge termination region located between the active region and a peripheral edge of the semiconductor structure, and the implanted regions provide termination rings that extend into the edge termination region.

Other devices, apparatus, and/or methods according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

FIG. 1 is a schematic cross-sectional view illustrating an example unit cell of a gate trench power semiconductor device including bottom shielding regions and support shielding regions.

FIG. 2 is a schematic cross-sectional view illustrating an example unit cell of a gate trench power semiconductor device including support shielding regions of lighter atomic weight materials according to some embodiments of the present disclosure.

FIG. 3 is a schematic cross-sectional view illustrating an example unit cell of a gate trench power semiconductor device including recessed support shielding regions of lighter atomic weight materials according to some embodiments of the present disclosure.

FIGS. 4A and 4B are schematic cross-sectional views illustrating example unit cells of gate trench power semiconductor devices including support shielding regions of lighter atomic weight materials formed by channeling ion implantation according to some embodiments of the present disclosure.

FIGS. 5A, 5B, and 5C are schematic cross-sectional views illustrating example unit cells of gate trench power semiconductor devices including recessed support shielding regions formed by channeling ion implantation according to some embodiments of the present disclosure.

FIGS. 6A, 6B, 6C, 6D, 6E, 6F, 6G, and 6H are schematic cross-sectional views illustrating example fabrication operations for forming power semiconductor devices including support shielding regions of lighter atomic weight materials according to some embodiments of the present disclosure.

FIG. 7 is a flow diagram illustrating methods of fabricating a power semiconductor device including support shielding regions of lighter atomic weight materials according to some embodiments of the present disclosure.

FIG. 8 is a schematic cross-sectional view illustrating an example unit cell of a planar gate power semiconductor device including support shielding regions of lighter atomic weight materials according to some embodiments of the present disclosure.

FIG. 9 is a schematic cross-sectional view illustrating an example unit cell of a junction barrier Schottky (JBS) diode including well regions of lighter atomic weight materials according to some embodiments of the present disclosure.

FIG. 10 is a schematic cross-sectional view illustrating an example unit cell of a trench JBS diode including well regions of lighter atomic weight materials according to some embodiments of the present disclosure.

FIG. 11 is a schematic cross-sectional view illustrating an example of an edge termination region of a power semiconductor device including termination rings of lighter atomic weight materials according to some embodiments of the present disclosure.

FIGS. 12A, 12B, 12C, 12D, 12E, 12F, 12G, and 12H are schematic cross-sectional views illustrating example fabrication operations for forming power semiconductor devices including support shielding regions of lighter atomic weight materials according to some embodiments of the present disclosure.

### DETAILED DESCRIPTION OF EMBODIMENTS

Some embodiments of the present disclosure are directed to improving the avalanche breakdown and switching performance of vertical power semiconductor devices, including planar device structures (such as planar MOSFETs or Schottky diodes) or trenched device structures (such as trenched MOSFET, trenched Schottky diodes, and IGBT devices). In trenched device structures, it may be important to avoid gate oxide field crowding in the vicinity of trench corners and provide a path for avalanche through a shielding network. In greater detail, in devices having gate electrodes and gate oxide (or other gate insulating layers) formed within trenches in the semiconductor structure, high electric fields may degrade the gate insulating layer over time, which may eventually result in failure of the device.

Many power semiconductor devices may include so-called deep or ‘buried’ shielding regions of a different conductivity type than the layer(s) of the semiconductor material underneath the well regions and/or gate electrodes of the device. For example, an implanted region of the opposite conductivity type (e.g., p-type) than the drift region (e.g., n-type) may be provided under the gate trenches, also referred to herein as a bottom shielding region. Such deep shielding regions may reduce the electric field levels in the gate insulating layer, particularly at corners of the gate trenches where the electric field levels may be more concentrated. The shielding regions may have the same conductivity type as the well regions, which is opposite the conductivity type of the drift region.

The deep shielding regions may typically include highly doped semiconductor regions having the same conductivity type as the channel region. Methods for doping a semiconductor material with n-type and/or p-type dopants include (1) doping the semiconductor material during the growth thereof, (2) diffusing the dopants into the semiconductor material and (3) using ion implantation to selectively implant the dopants in the semiconductor material. When silicon carbide is doped during epitaxial growth, the dopants tend to unevenly accumulate, and hence the dopant concentration may vary by, for example, +/−15%, which can negatively affect device operation and/or reliability. Additionally, doping by diffusion may not be an option in silicon carbide, gallium nitride and various wide band-gap semiconductor devices since conventional n-type and p-type dopants tend to not diffuse well (or at all) in those materials, even at high temperatures.

In light of the above, ion implantation is often used to dope wide band-gap semiconductor materials, such as silicon carbide. However, in gate-trench vertical power devices (also referred to herein as trenched vertical power devices or trenched gate devices), it may be desirable to form deep shielding regions underneath the well regions and/or gate electrodes of the device, and these deep shielding regions often extend into the device to depths of about 1-3 microns or more. The depth at which the ions are implanted is directly related to the energy of the implant, i.e., ions implanted into a semiconductor layer at higher energies tend to go deeper into the layer.

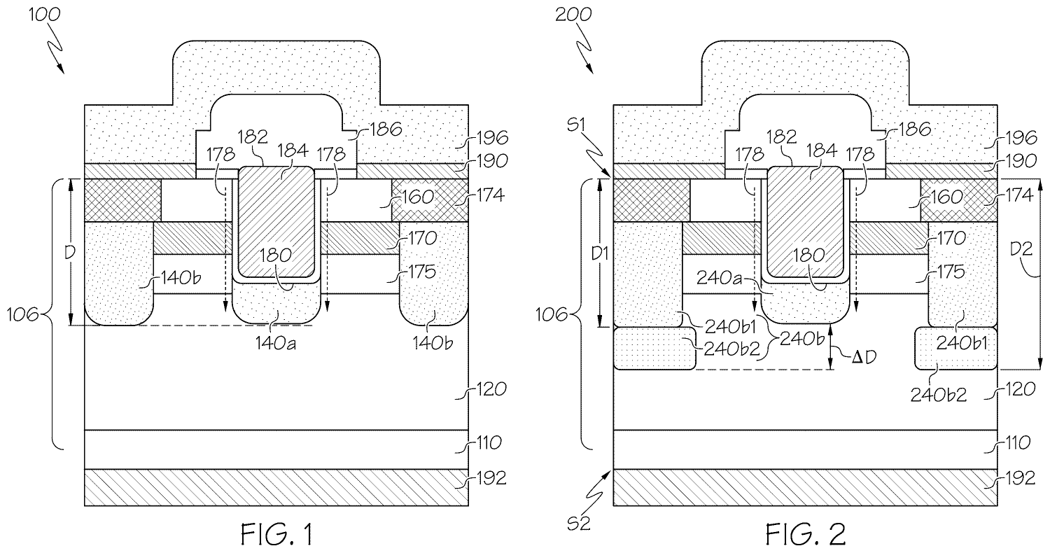

FIG. 1 is a schematic cross-sectional view illustrating an example unit cell of a trenched vertical power device (illustrated as power MOSFET 100) including deep buried P-type shielding regions 140a, 140b formed by ion implantation. As shown in FIG. 1, the power MOSFET 100 includes a heavily-doped (e.g., N⁺) first conductivity type (e.g., n-type) substrate 110. A lightly-doped (e.g., N⁻) first conductivity type drift layer or region 120 is provided on the substrate 110, for example by epitaxial growth. The drift region 120 may be wide bandgap semiconductor material (such as silicon carbide (SiC)) in some embodiments. For example, the substrate 110 may be a 4H-SiC substrate, and the drift region 120 may be one or more 4H-SiC n-type epitaxial layers formed on the substrate 110. A portion of the drift region 120 may include a current spreading layer (“CSL”) of the first conductivity type having a higher dopant concentration than the lower portions of the drift region 120. A moderately-doped second conductivity type (e.g., p-type) layer is formed on or in (for example, by epitaxial growth or implantation) the drift region 120 and acts as the well regions (e.g., “P-wells”) 170 for the device 100. Heavily-doped second conductivity type (e.g., P⁺) regions 174 are formed in the well regions 170, for example, via ion implantation. The transistor channels or conduction paths 178 may be formed in the moderately-doped regions P-wells 170. The substrate 110, drift region 120 (including current spreading layer 185), and the moderately doped layer defining the P-wells 170, along with the various regions/patterns formed therein, are included in a semiconductor structure 106 of the MOSFET 100.

Still referring to FIG. 1, trenches 180 are formed in the semiconductor structure 106, e.g., with ‘striped’ gate trench layouts in which the trenches 180 continuously extend in parallel to one another in a longitudinal direction. The trenches 180 are spaced apart in a lateral direction crossing (e.g., perpendicular to) the longitudinal direction, and extend into the drift region 120 toward the substrate 110 in a vertical direction. The trenches 180 (in which the gates 184 are formed) may be formed to extend through the moderately-doped layer 170 to define the respective P-wells. Heavily-doped (e.g., P⁺) second conductivity type shielding regions 140a, 140b are formed in the drift region 120, for example, by ion implantation. The shielding regions 140a, 140b may be in electrical connection with the P-wells 170. A gate insulating layer 182 (e.g., a gate oxide) is conformally formed on the bottom surface and sidewalls of each trench 180. The corners of the gate trench 180 and the gate insulating layer 182 thereon may be rounded even if illustrated otherwise.

A gate electrode 184 (or “gate”) is formed on each gate insulating layer 182 to fill the respective gate trenches 180. Portions of the drift region 120 that are under and/or adjacent the gate electrode 184 may be referred to as the “JFET region” 175. Vertical transistor channel regions (with conduction 178 shown by dotted arrows) are defined in the well regions 170 adjacent the gate insulating layer 182. Heavily-doped source regions 160 of the first conductivity type (e.g. N⁺) are formed in upper portions of the P-wells 170, for example, via ion implantation. The heavily-doped regions 174 of the second conductivity type (e.g., a P+) contact the well regions 170. Source contacts 190 are formed on the source regions 160, on the heavily-doped regions 174, and on the deep shielding regions 140b. The source contacts 190 may be ohmic metal in some embodiments. A drain contact 192 is formed on the lower surface of the substrate 110. A gate contact (not shown) may be electrically connected to each gate electrode 184, for example, by a conductive gate bus (not shown). An intermetal dielectric layer 186 may be formed on the gates 184, and a metal (e.g., aluminum) layer 196 may be formed on the intermetal dielectric layer 186 to contact the source contacts 190. The source contacts 190 may extend on to the intermetal dielectric 186 layer in some embodiments, and may comprise, for example, diffusion barrier and/or adhesion layers.

As noted above, some devices may be susceptible to premature oxide breakdown due to the electric field crowding effect near the corners of the gate trench 180. Providing bottom shielding regions 140a under the gate trenches 180 may provide a path for avalanche current, but to do so, an appropriate contact mechanism to the bottom shielding regions 140a must be established. Various methods may be used to provide electrical contact to the bottom shielding regions 140a. For example, one side of the trenches 180 may be implanted with high energy p-type dopants to contact the bottom shielding regions 140a; however, such methods may limit the current path 178 to only one sidewall of the trenches 180, which may adversely affect on-state channel conduction. Alternatively, the bottom shielding regions 140a may be connected in a segmented manner to provide electrical contact, but such segmented connections may require avalanche current to pass through highly resistive p-type implants, which may reduce or sacrifice device reliability.

In the examples of FIG. 1, multiple deep buried semiconductor regions or shielding patterns 140a, 140b of an opposite conductivity type than the drift region 120 are configured to prevent degradation of the trench MOSFET 100 at high electric fields. In particular, the shielding patterns or regions 140a, 140b at the bottom (140a) and along sidewalls (140b) of the gate trenches 180 are configured to provide electric field (e.g., voltage and/or current) blocking by connections to respective source contacts 190, which are connected to ground. This may help protect the gate insulating layer 182 at the lower corner region(s) of the gate trenches 180 from high electric fields during reverse blocking operation. Shielding connection patterns may be connected to the source contacts 190 at the top of the device 100 (or may be otherwise connected to the deep shielding patterns 140a, 140b) to allow the shielding patterns 140a, 140b to be electrically grounded.

Some embodiments of the present disclosure may arise from realization that forming multiple shielding regions 140a, 140b to sufficient depths D in the drift regions 120 may require high energy ion implantation, as the depths D are directly related to the energy of the implant, i.e., ions implanted into a semiconductor layer at higher energies tend to go deeper into the layer. For example, some approaches may use either random or channeling implant of p-type aluminum (Al) ions to provide bottom shielding regions 140a and support shielding regions 140b. For reliable switching operation and/or handling avalanche current appropriately, it may be beneficial for the support shielding regions 140b to extend deeper into the semiconductor structure than the bottom shielding regions 140a. The depth and separation between these shielding regions 140a and 140b typically depends on the doping near the bottom of the support shielding regions 140b.

To achieve higher doping concentration, higher doses of ion implantation may be required, and to achieve additional depth, higher energy ion implantation may be necessary. Both the higher implant dosage and the higher implant energy can impose limitations. In particular, when dopant ions are implanted into a semiconductor layer, the ions damage the crystal lattice of the semiconductor layer. This lattice damage can typically only be partly repaired by thermal annealing processes. That is, the lattice damage caused by the ion implantation process may not be completely repaired. Moreover, the amount of lattice damage may also be directly related to the implant energy, with higher energy implants tending to cause more lattice damage than lower energy implants. The uniformity of the dopant concentration also tends to decrease with increasing implant depth.

Considering these limitations, shielding regions 140a, 140b in power semiconductor devices may be designed to have shallower trench depth, so as to ensure sufficient separation between the two shielding regions 140a, 140b given the high dose and energy of the implantation processes that may be required to provide the desired shielding. As an alternative, channeling implantation may be used to form the shielding regions 140a, 140b. In channeling implantation, the implanted ions may travel between atomic lattice structures of the semiconductor material, so as to provide deeper penetration. However, this too may involve limitations in that after a certain dose, the channeling implant may be de-channeled and the desired profile for the shielding regions 140a, 140b may not be obtained.

Embodiments of the present disclosure may provide semiconductor structures in which shielding regions including dopants (e.g., p-type) of a lighter atomic weight than some conventional dopants (e.g., Al) are used to achieve greater implant depths without increasing implantation energy, so as to provide reliable switching and reduced or minimum resistance to avalanche current flow through the semiconductor structure. In greater detail, some embodiments described herein may be directed to conditions and mechanisms that can achieve improved avalanche and/or switching performance by providing implanted regions (e.g., support shielding regions) of lighter atomic weight materials adjacent a first side of the semiconductor structure. The implanted regions have the opposite conductivity type (e.g., p-type) than the drift region (e.g., n-type), and include a first dopant material (such as, but not limited to, aluminum (Al)) and a second dopant material that has a lighter atomic weight than the first dopant material. For example, the second dopant material may include but is not limited to, boron (B), beryllium (Be), and/or magnesium (Mg). The implanted regions may be formed to provide support shielding regions and/or bottom shielding regions (in transistor devices), well regions (in Schottky diodes), and/or edge termination rings. In one example, the implanted regions may be formed by co-implanting Al (as the heavier atomic weight material) and B/Be/Mg (as the lighter atomic weight material), or implanting B/Be/Mg alone, using random and/or channeling ion implantation techniques. In particular, some embodiments described herein may utilize Al and B co-implantation (or B implantation alone) to take advantage of properties of B diffusion (laterally and/or vertically) in SiC semiconductor structures.

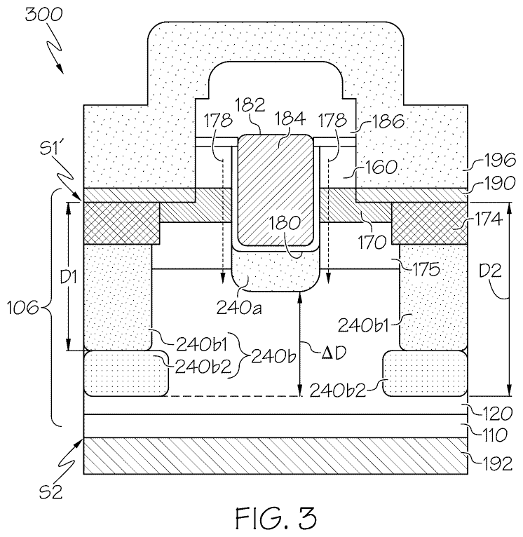

FIG. 2 is a schematic cross-sectional view illustrating an example unit cell of a gate trench power semiconductor device (illustrated as power MOSFET 200) including support shielding regions of lighter atomic weight materials according to some embodiments of the present disclosure. Like components, elements, and/or layers of the various embodiments described herein may be referred to by like reference designators throughout, and repeated descriptions of like or similar components, elements, and/or layers may be omitted for brevity.

As shown in FIG. 2, the power MOSFET 200 includes a semiconductor structure 106 similar to that of FIG. 1, with a substrate 110 and a drift region 120 of a first conductivity type (e.g., n-type) and implanted regions 240 of a second conductivity type (e.g., p-type). The drift region 120 may be wide bandgap semiconductor material (such as SiC), and may include a current spreading layer of the first conductivity type having a higher dopant concentration than the lower portions of the drift region 120, a moderately-doped second conductivity type (e.g., p-type) layer that acts as the well regions (e.g., “P-wells”) 170, and heavily-doped second conductivity type (e.g., P⁺) regions 174 formed in the well regions 170, with vertical transistor channels or conduction paths 178 (shown by dotted arrows) being formed in the moderately-doped regions P-wells 170.

The power MOSFET 200 of FIG. 2 is shown as a trenched structure, including gate insulating layers 182 and gates 184 formed in gate trenches 180 that extend in parallel to one another in a longitudinal direction (e.g., a first horizontal direction), are spaced apart in a lateral direction (e.g., a second horizontal direction) that crosses (e.g., is perpendicular to) the longitudinal direction, and extend from a first side or surface S1 of the semiconductor structure 106 into the drift region 120 toward the substrate 110 on a second side or surface S2 (e.g., in a vertical direction). Portions of the drift region 120 that are under and/or adjacent the gate electrode 284 provide the “JFET region” 175. Heavily-doped source regions 160 of the first conductivity type (e.g. N⁺) are formed in upper portions of the P-wells 170, and source contacts 190 are formed on the source regions 160 and on the heavily-doped regions 174 on the first side S1 of the semiconductor structure 106. The source contacts 190 may be ohmic metal in some embodiments. A drain contact 192 is formed on the lower surface of the substrate 110 on the second side S2, a gate contact (not shown) may be electrically connected to each gate electrode 184, an intermetal dielectric layer 186 may be formed on the gates 184, and a metal layer 196 may be formed on the intermetal dielectric layer 186 to contact the source contacts 190.

Still referring to FIG. 2, implanted regions 240b extend from adjacent the first side S1 of the semiconductor structure 106 towards the second side S2, beyond the bottom surface of the gate trenches 180. For example, heavily-doped (e.g., P⁺) regions 240b of the second conductivity type may be implanted into the first side or surface S1 of the drift region 120 on opposite sides of the gates 184 and spaced apart from sidewalls of the gate trenches 180. The implanted regions 240b include portions 240b2 (also referred to herein as second portions) of dopant materials having a lighter atomic weight than aluminum. The implanted regions 240b may also include first portions 240b1 of heavier atomic weight dopant materials (such as aluminum), with the second portions 240b2 provided between the first portions 240b1 and the second side S2 of the semiconductor structure 106. That is, the implanted regions 240b may include shallower (“first”) implanted regions 240b1 of a first dopant material, and deeper (“second”) implanted regions 240b2 of a second dopant material. The second dopant material has an atomic weight lighter that is than an atomic weight of the first dopant material. In particular, the second dopant material may include elements (such as boron (B), beryllium (Be), and/or magnesium (Mg)) that have a lighter atomic weight than that of aluminum (Al), which may be used as the first dopant material.

In the embodiment of FIG. 2, the implanted regions 240b function as support shielding regions 240b for the MOSFET 200. For example, Al may be implanted into the semiconductor structure 106 to form first support shielding portions 240b1 including Al, while B (or Be or Mg) may be implanted into the semiconductor structure 106 to form second support shielding portions 240b2 including B (or Be or Mg) between the first support shielding regions 240b1 and the substrate 110. As the second dopant material (e.g., B, Be, or Mg) is lighter in atomic weight than the first dopant material (e.g., Al), the second dopant material may penetrate further into the material of the drift region 120 (e.g., SiC) with a same or similar implant energy as used to implant the first dopant material. That is, at any specific implantation energy, the depth D2 of the second portions 240b2 will be greater than the depth D1 of the first portions 240b1 (as measured relative to the first surface S1). In some embodiments, the implant energy range for the first implantation process (to form the first portions 240b1 of the heavier atomic weight dopant material) and the second implantation process (to form the second portions 240b2 of the lighter atomic weight dopant material) can each be about 1000 keV to about 4000 keV (with the higher end of the range being mainly limited by implant mask process and tool capabilities).

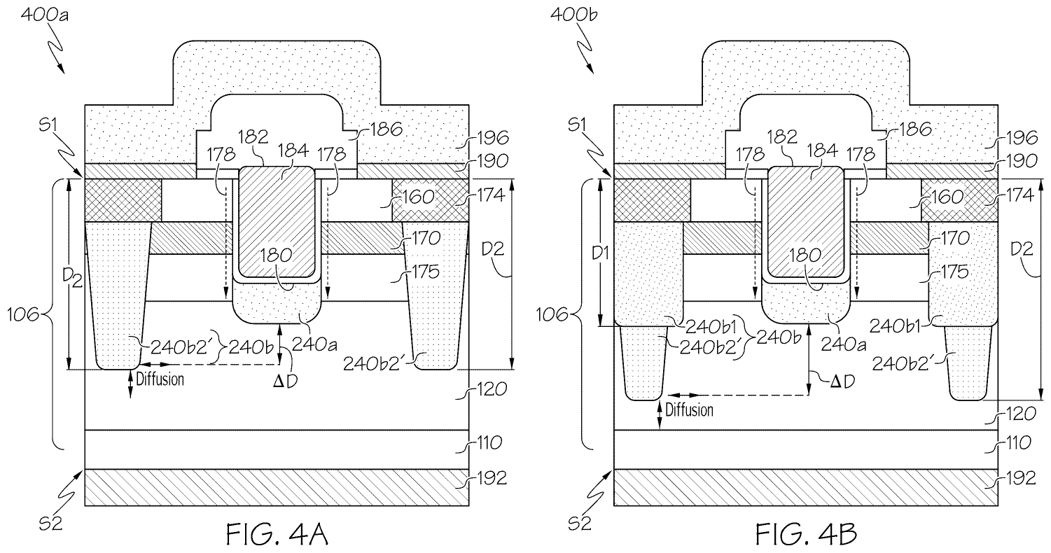

The support shielding regions 240b may be electrically connected to the source contact 190 in each cell 200 (e.g., by higher dopant concentration regions 174 therebetween), and may offer comparatively lower or minimal resistance to avalanche current flow therethrough. In some embodiments, the support shielding regions 240b may be provided in combination with additional heavily-doped (e.g., P⁺) implanted regions 240a of the second conductivity type, which (in the embodiments of FIG. 2) function as bottom shielding regions 240a beneath the bottom surfaces of the trenches 180. The bottom shielding regions 240a may include either the first or second dopant material. The support shielding regions 240b may extend towards the second side S2 of the semiconductor structure 106, beyond the bottom shielding regions 240a. While illustrated in FIG. 2 (and in FIGS. 3 to 5C) as including the bottom shielding region 240a, in some embodiments, the device 200 (and likewise, the devices 300, 400a, 400b, and 500a to 500c) may be free of the bottom shielding region 240a.

After implant activation, the second, lighter atomic weight material may diffuse both laterally (e.g., towards the gates 184) and vertically (e.g., towards the substrate 110). The second portions 240b2 of the implanted regions 240 may thus laterally extend (e.g., towards each other) beyond the first portions 240b1, such that lateral spacings between adjacent implanted regions 240b are non-uniform over their respective depths D2. As lateral diffusion of the second dopant material in the drift region 120 may cause the second portions 240b2 of the implanted regions 240 to extend toward the channel regions 178 (and thereby hamper on-state characteristics), shallower implants (to depth D1) can be formed by implantation of the first dopant material to form the first portions 240b1, and deeper implants (to depth D2) can be formed by implantation of the second dopant material to form the second portions 240b2, such that the second portions 240b2 may be sufficiently separated from the channel regions 178 even after lateral diffusion of the second dopant material in the drift region 120. Support shielding regions 240b including first portions 240b1 of a heavier atomic weight material and second portions 240b2 of a lighter atomic weight material can thus achieve greater depths D2 while providing design margin with sufficient separation between support shielding regions 240b and bottom shielding regions 240a at the bottom of the gate trenches 180 so as to provide improved avalanche performance.

Some embodiments of the present disclosure may thereby advantageously utilize diffusion properties of dopant materials having an atomic weight less than Al (e.g., B, Be, or Mg) in semiconductor structures (e.g., SiC) to achieve implanted regions 240b with greater depths D2 using the same or lower implantation energy than may typically be used to implant heavier dopant materials (e.g., Al), and thus reduced lattice damage to the semiconductor structure 106. Random ion implantation and/or channeling ion implantation may be used to implant the first dopant material and/or the second dopant material to form the first portions 240b1 and/or the second portions 240b2 of the implanted regions 240b, respectively. Various techniques may also be used to limit diffusion of the second, lighter atomic weight dopant material in the semiconductor structure. For example, channeling ion implantation may be used to limit lateral diffusion of the lighter atomic weight material in the drift region 120, thereby resulting in second portions 240b2 of the implanted regions 240b that taper with depth D2. Also, in some embodiments, an additional material that is configured to reduce diffusion of the second dopant material may be co-implanted along with the second dopant material. For example, carbon (C) may be co-implanted with B, Be, or Mg to suppress or otherwise control diffusion (lateral and/or vertical) of the lighter atomic weight material in the drift region 120.

Additional recessing operations may also be used to achieve implanted regions 240b with greater depths D2. FIG. 3 is a schematic cross-sectional view illustrating an example unit cell of a gate trench power semiconductor device (illustrated as power MOSFET 300) including recessed support shielding regions 240b of lighter atomic weight materials according to some embodiments of the present disclosure.

As shown in FIG. 3, the power MOSFET 300 includes a semiconductor structure 106 similar to that of FIG. 2, but with the surface S1′ of the drift region 120 recessed relative to portions of the drift region 210 therebetween. For example, a mask may be formed on the semiconductor structure 106, and portions of the drift region 120 exposed by openings in the mask may be selectively etched, thereby recessing the surface S1′. Thereafter, first and second ion implantation processes may be performed (in some embodiments, using the same mask as used in the selective etching process) to form the first portions 240b1 and the second portions 240b2 of the implanted regions 240b.

Due to the recessed surface S1′, the implanted regions 240b may extend further towards the substrate 110, without an increase in the implantation energy. For example, where the drift region 120 is SiC, etching of the SiC drift region 120 can be performed, followed by Al implantation and B implantation (using the same or similar implant energy) to form the first portions 240b1 of the first dopant material extending to depth D1 and the second portions 240b2 of the second dopant material extending to a greater depth D2, respectively. The implanted regions 240b in the power MOSFET 300 of FIG. 3 may thus be formed using similar processes and dopant materials as in the power MOSFET 200 of FIG. 2, but may extend closer to the substrate 110 (and beyond the bottom shielding region 240a with a comparatively greater difference in depth ΔD) than the implanted regions 240b of FIG. 2, due to the pre-implantation recessing of the surface S1′.

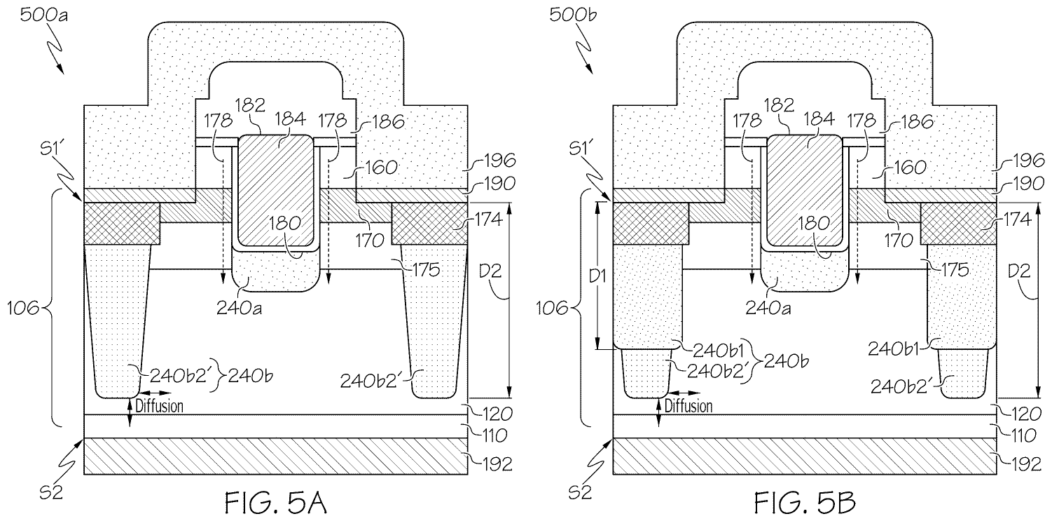

Also, as noted above, channeling ion implantation may be used in some embodiments to implant the first dopant material and/or the second dopant material to form the first portions 240b1 and/or the second portions 240b2 of the implanted regions 240b, respectively. FIGS. 4A and 4B are schematic cross-sectional views illustrating example unit cells of gate trench power semiconductor devices including support shielding regions 240b of lighter atomic weight materials formed by channeling ion implantation according to some embodiments of the present disclosure.

As shown in FIGS. 4A and 4B, the power MOSFETs 400a and 400b include semiconductor structures 106 similar to that of FIG. 2, but the implanted regions 240b include second portions 240b2′ with an implant profile that is tapered towards the second surface S2 over the depth D2. For example, a channeling ion implantation process may be used to implant the second, lighter atomic weight material (e.g., B, Be, or Mg) to form the second portions 240b2′ in the semiconductor structure 106 adjacent the first side S1 to the depth D2. As shown, the second portions 240b2′ have a tapered implant profile such that, after implant activation, diffusion of the lighter atomic weight dopant material (which may occur laterally and/or vertically in the drift region 120) may not reach the on-state current conduction path or channel 178. The implanted regions 240b may include the second portions 240b2′ having the tapered implant profile alone (as shown in FIG. 4A) or in combination with the first portions 240b1 of the first dopant material (as shown in FIG. 4B). The first dopant material may be implanted by random ion implantation (to form the first portions 240b1 as shown in FIG. 4B) or by channeling ion implantation (to form the first portions 240b1 with a tapered implant profile). In other words, channeling ion implantation of the second, lighter atomic weight material may be performed in combination with (random or channeling) implantation of the first, comparatively heavier atomic weight material (as shown in FIG. 4B), or without implantation of the first dopant material (as shown in FIG. 4A).

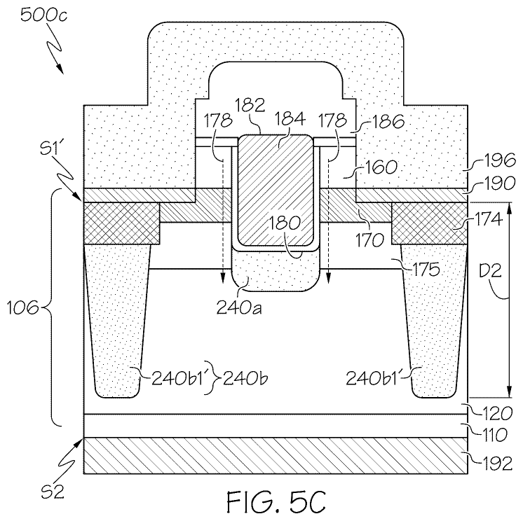

It will be understood that features and/or fabrication processes of embodiments described herein may be combined in various ways to provide implanted regions 240b including second portions 240b2, 240b2′ of second dopant materials having a lighter atomic weight than Al. For example, FIGS. 5A, 5B, and 5C are schematic cross-sectional views illustrating example unit cells of gate trench power semiconductor devices including recessed support shielding regions formed by channeling ion implantation according to some embodiments of the present disclosure.

As shown in FIGS. 5A and 5B, the power MOSFETs 500a and 500b include semiconductor structures 106 similar to that of FIG. 3 (i.e., with the surface S1′ of the drift region 120 recessed relative to portions of the drift region 210 therebetween), in combination with implanted regions 240b including second portions 240b2′ having an implant profile that is tapered towards the second surface S2 over the depth D2. For example, portions of the drift region 120 exposed by openings in a mask may be selectively etched to recess the surface S1′, and thereafter, a channeling ion implantation process may be performed (in some embodiments, using the same mask as used in the selective etching process) to form the implanted regions 240b including second portions 240b2′ of the second, lighter atomic weight material (e.g., B, Be, or Mg) with the tapered implant profile in the semiconductor structure 106 adjacent the first side S1 to the depth D2. The implanted regions 240b may include the second portions 240b2′ having the tapered implant profile alone (as shown in FIG. 5A) or in combination with the first portions 240b1 of the first dopant material (as shown in FIG. 5B).

The first dopant material may be implanted using random ion implantation (to form the first portions 240b1 shown in FIG. 5B) or by channeling ion implantation (to form the first portions 240b1′ with a tapered implant profile as shown in FIG. 5C). Further embodiments may include implanted regions 240b with first portions 240b1′ of the first dopant material alone (e.g., as formed by channeling ion implantation), as shown FIG. 5C. The power MOSFET 500c of FIG. 5C includes a semiconductor structure 106 similar to that of FIG. 3 (i.e., with the surface S1′ of the drift region 120 recessed relative to portions of the drift region 210 therebetween), in combination with implanted regions 240b including first portions 240b1′ of the first dopant material (e.g., Al) having an implant profile that is tapered towards the second surface S2 over the depth D2. That is, B/Be/Mg channeling (as shown in FIG. 5A), Al and B/Be/Mg random and channeling implant combinations (as shown in FIG. 5B), or Al channeling (as shown in FIG. 5C) can be performed to provide implanted regions 240b (illustrated by way of example as support shielding regions).

More generally, in embodiments of the present disclosure, channeling ion implantation may be used to form the portions 240b2′ of the second dopant material (as shown in FIG. 5A), the portions 240b1′ of the first dopant material (as shown in FIG. 5C), or combinations thereof 240b1 and 240b2′ (as shown in FIG. 5B) with greater depths D2, without increasing implantation energies. For example, implant depths D1 that may be achieved with random Al implantation (based on process capabilities and implant tool limitations) may be about 1.5 μm to about 2.6 μm. In contrast, implant depths D2 using a dopant material that is lighter than Al (e.g., B, Be, or Mg) in accordance with embodiments described herein may be about 1.5 μm to about 3.1 μm, with similar energy range, even before further diffusion in the drift region (e.g., in 4H-SiC). That is, while the implanted Al regions 240b1 may not diffuse in 4H-SiC, the implanted B (or Be, or Mg) regions 240b2 may further diffuse in 4H-SiC drift region 120, and may do so as a function of implant activation process parameters. The difference in depth between D1 and D2 may also depend on the background doping of the drift region 120. In some embodiments, the difference in depth (D2−D1) may be about 0.3 μm to about 2.0 μm.

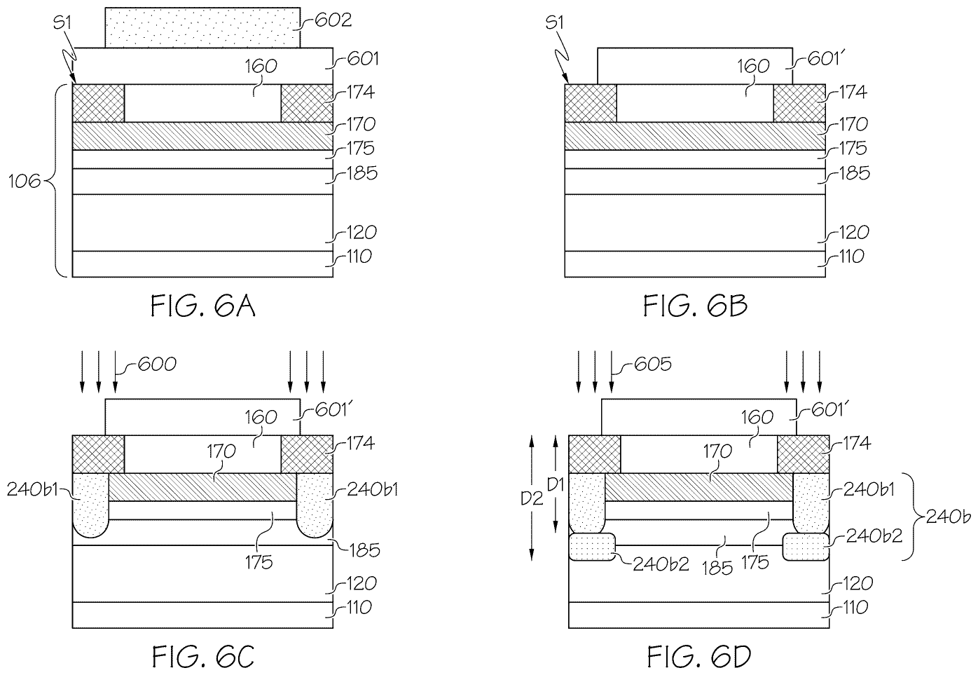

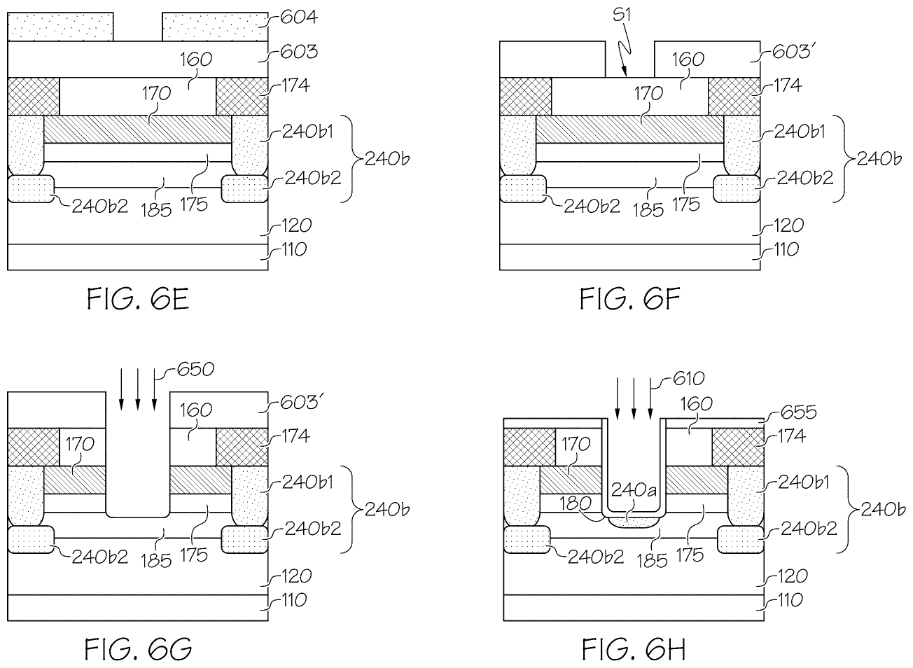

FIGS. 6A to 6H are schematic cross-sectional views illustrating example fabrication operations for forming power semiconductor devices including support shielding regions of lighter atomic weight materials according to some embodiments of the present disclosure. FIG. 7 is a flow diagram illustrating methods of fabricating a power semiconductor device including support shielding regions of lighter atomic weight materials according to some embodiments of the present disclosure.

Referring to FIG. 6A and FIG. 7, a semiconductor structure 106 including a drift region 120 of a first conductivity type (e.g., n-type) is provided (block 705). The semiconductor layer structure 106 may further include a current spreading layer 185, a JFET region 175, a well region 170, a source region 160, and heavily doped regions 174 of the second conductivity type, as described above. The semiconductor structure 106 may include a substrate 110 and/or other layers. In some embodiments, the drift region 120 may be one or more silicon carbide (SiC) epitaxial layers on a SiC substrate 110. A mask layer 601 is formed on a first side or surface S1 of the semiconductor structure 106, and a patterning layer 602 is formed on the mask layer 601.

In FIG. 6B, the mask layer 601 is patterned (e.g., photolithographically) using the patterning layer 602 to form an implant mask pattern 601′ including openings therein exposing portions of the first surface S1 of the drift region 120 (block 710). In FIGS. 6C and 6D, a first ion implantation process 600 and a second ion implantation process 605 are performed (at block 715) using the same mask pattern 601′ to form implanted regions 240b of first and second dopant materials of a second conductivity type (e.g., p-type) in the portions of the drift region 120 exposed by the mask pattern 601′. The implanted regions 240b include first portions 240b1 of a first dopant material and second portions 240b2 of a second dopant material, which extend to first and second depths D1 and D2, respectively, relative to the first surface S1. The second dopant material has a lighter atomic weight than the first dopant material, e.g., lighter than aluminum. For example, the second dopant material may include boron (B), beryllium (Be), and/or magnesium (Mg).

A dose and/or implantation energy of each of the ion implantation processes 600 and 605 shown in FIGS. 6C and 6D may be controlled to form the portions 240b1 and 240b2 of the implanted regions 240b with desired dopant concentrations and/or desired depths relative to the first surface S1. However, as the second dopant material is lighter in atomic weight than the first dopant material, the different depths D1 and D2 of the portions 240b1 and 240b2 may be achieved using a same or substantially similar implantation energy for both implantation processes 600 and 605, with the second depth D2 greater than the first depth D1. The dopant concentrations of the portions 240b1 and 240b2 may be substantially uniform or graded (e.g., stepwise or continuous). In other embodiments, the dose and/or implantation energy of the second ion implantation process 605 may be different than the first ion implantation process 600.

Following the ion implantation processes 600 and 605, an implant activation process may be performed, which may cause the second portions 240b2 of the implanted regions 240 containing the second dopant material to diffuse in the semiconductor structure 106, vertically (towards the substrate 110) and/or laterally (towards one another, e.g., beyond the first portions 240b1). The first ion implantation process 600 (using the heavier dopant material) may be performed prior to the second ion implantation process 605 (using the lighter dopant material), or vice versa. Any combination of random ion implantation and channeling ion implantation may be used for the ion implantation processes 600 and 605, each with tradeoffs over control of implantation depth versus implant diffusion. For example, channeling ion implantation may be used for the second ion implantation process 605 (thereby resulting in implanted portions 240b2′ that taper with depth, as shown in FIGS. 4A and 4B) to limit lateral diffusion of the second portions 240b2 including the second, lighter atomic weight dopant material towards one another. The second ion implantation process 605 may further include co-implantation of the second dopant material with an additional material (e.g., carbon (C)), which may suppress or otherwise control diffusion (both lateral and vertical).

In some embodiments, after the implant mask pattern 601′ is defined in FIG. 6B, the portions of the drift region 120 exposed by the openings in the mask 601′ may be recessed (e.g., via one or more etching processes) before performing the implantation processes 600 and/or 605 of FIGS. 6C and/or 6D (thereby resulting in the recessed surface S1′ as shown in FIGS. 3 and 5A to 5C). Due to the recessed surface S1′, the implanted regions 240b may extend further towards the substrate 110, without an increase in the implantation energy of the implantation processes 600 and/or 605.

In FIG. 6E, the mask 601′ is removed, an etching mask layer 603 (e.g., an oxide layer) is formed on the first surface S1 of the semiconductor layer structure 106, and a patterning layer 604 is formed on the etching mask layer 603. In FIG. 6F, the etching mask layer 603 is patterned using the patterning layer 604 to form an etch mask pattern 603′ including openings therein exposing portions of the first surface S1 of the semiconductor layer structure 106 between the implanted regions 240b. In FIG. 6G, an etching process 650 is performed to selectively etch the portions of the first surface S1 exposed by the etching mask pattern 603′, thereby forming gate trenches 180 in the semiconductor structure 106 between and laterally spaced apart from the implanted regions 240b.

In FIG. 6H, a mask 655 (e.g., an oxide mask) is formed on sidewalls and on a bottom surface of the gate trenches 180. For example, the trenches 180 may be oxidized and/or a coating may be deposited along the sidewalls and bottom surface of the gate trenches 180 to form the mask 655. In some embodiments, portions of the mask 655 on the sidewalls may be formed thicker than portions of the mask 655 on the bottom surface of the gate trenches 180, for example, to protect the conducting sidewalls of the trench 180 from a subsequent implant process 610, which may be used to form bottom shielding structures 240a.

In particular, one or more ion implantation processes 610 may be performed to implant a dopant material of the second conductivity type into the bottom surface of the trenches 180 using the mask 655 as an implantation mask to form bottom shielding regions 240a under and extending at least partially along the bottom surface of the gate trenches 180. The bottom shielding regions 240a may include the first (heavier atomic weight) dopant material or the second (lighter atomic weight) dopant material in some embodiments. A dose and/or implantation energy of the implantation process(es) 610 may be controlled to form the bottom shielding structures 240a with desired dopant concentrations and/or desired depths relative to the first surface S1, and/or with a dopant concentration that is substantially uniform or graded. Subsequently, the mask 655 is removed, a gate oxide layer 182, gate electrode 184, source contacts 190, intermetal dielectric 186, and metal layer 196 may be formed on the first surface S1, and a drain contact 192 may be formed on the second surface S2 to provide the device of FIG. 2, with the implanted regions 240b providing support shielding regions 240b for the power MOSFET 200.

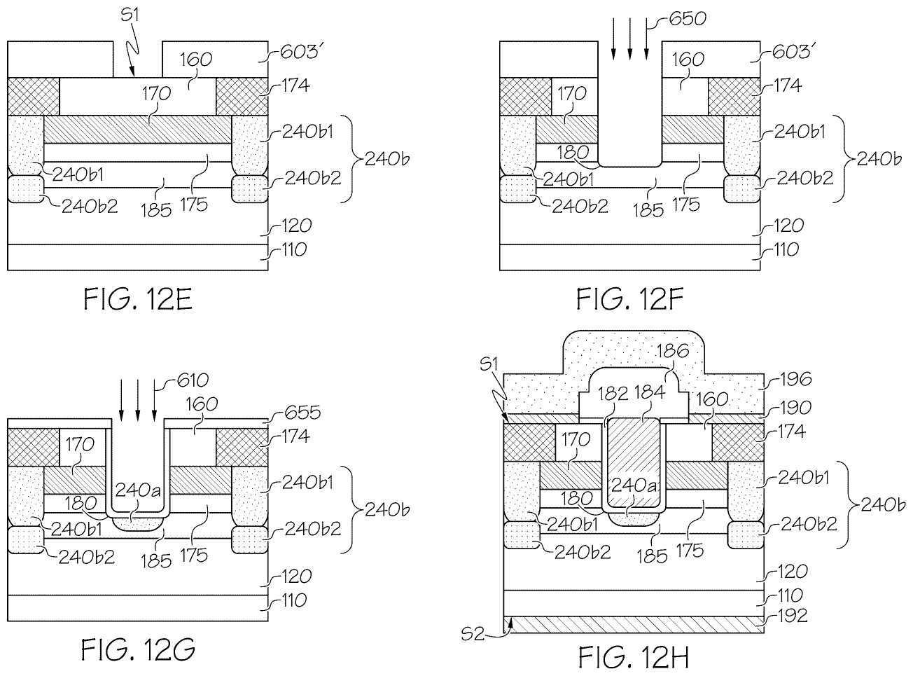

FIGS. 12A to 12H are schematic cross-sectional views illustrating alternative example fabrication operations for forming power semiconductor devices including support shielding regions of lighter atomic weight materials according to some embodiments of the present disclosure. Operations similar to those described with reference to FIGS. 6A to 6H may be omitted for brevity.

Referring to FIG. 12A and FIG. 7, a semiconductor structure 106 including a drift region 120 of a first conductivity type (e.g., n-type) is provided (block 705), and an implant mask pattern 601′ including openings therein exposing portions of the first surface S1 of the drift region 120 (block 710) is formed. In FIG. 12B, a first ion implantation process 600 is performed (block 715) using a first (comparatively heavier atomic weight) dopant material to form the first portions 240b1 of the implanted regions 240b extending to the first depth D1 in the semiconductor structure 106.

In FIG. 12C, a spacer pattern 1201 is formed on the implant mask pattern 601′, and a second ion implantation process 605 is performed (block 715) using a second (comparatively lighter atomic weight) dopant material to form second portions 240b2 of the implanted regions 240b in the semiconductor structure 106 below the first portions 240b1, that is, between the first portions 240b1 and the second surface S2 of the semiconductor structure 106. As the second dopant material is lighter in atomic weight than the first dopant material, the different depths of the portions 240b1 and 240b2 may be achieved using a same or substantially similar implantation energy for both implantation processes 600 and 605. As the spacer pattern 1201 covers portions of the first surface S1 that are exposed by the openings in the implant mask pattern 601′, the second portions 240b2 of the second dopant material are laterally spaced apart from one another further than the first portions 240b1 of the first dopant material. That is, responsive to the second implantation process 605 (and prior to implant activation), the second portions 240b2 of the second dopant material may not laterally extend beyond the first portions 240b1.

Following the ion implantation processes 600 and 605, an implant activation process may be performed, which may cause the second portions 240b2 of the implanted regions 240 containing the second dopant material to diffuse in the semiconductor structure 106, vertically (towards the substrate 110, to the second depth D2) and/or laterally (towards one another), as shown in FIG. 12D. However, forming the second portions 240b2 of the implanted regions 240 using the implant mask pattern 601′ with the spacer pattern 1201 formed thereon (as shown in FIG. 12C) may limit lateral extension of the second portions 240b2 including the second, lighter atomic weight dopant material towards one another. In some embodiments, the second portions 240b2 may not laterally extend beyond the first portions 240b1 (even after diffusion), thereby ensuring further separation of the second portions 240b2 including the second dopant material from the channel region (e.g., along sidewalls of the gate trench 180) formed in subsequent operations.

After performing the second ion implantation process 605 in FIG. 12C, operations may continue in a manner similar to FIGS. 6E to 6H. In particular, as shown in FIG. 12D, the mask 601′ is removed, an etching mask layer 603 (e.g., an oxide layer) is formed on the first surface S1 of the semiconductor layer structure 106, and a patterning layer 604 is formed on the etching mask layer 603. In FIG. 12E, the etching mask layer 603 is patterned using the patterning layer 604 to form an etch mask pattern 603′ including openings therein exposing portions of the first surface S1 of the semiconductor layer structure 106 between the implanted regions 240b. In FIG. 12F, an etching process 650 is performed to selectively etch the portions of the first surface S1 exposed by the etching mask pattern 603′, forming gate trenches 180 in the semiconductor structure 106 between and laterally spaced apart from the implanted regions 240b. In FIG. 12G, a mask 655 (e.g., an oxide mask) is formed on sidewalls and on a bottom surface of the gate trenches 180, and one or more ion implantation processes 610 may be performed to implant a dopant material of the second conductivity type into the bottom surface of the trenches 180 using the mask 655 as an implantation mask to form bottom shielding regions 240a under and extending at least partially along the bottom surface of the gate trenches 180. In FIG. 12H, the mask 655 is removed, a gate oxide layer 182, gate electrode 184, source contacts 190, intermetal dielectric 186, and metal layer 196 may be formed on the first surface S1, and a drain contact 192 may be formed on the second surface S2 to provide a power MOSFET 1200.

FIGS. 6A to 6H and FIGS. 12A to 12H illustrate methods of forming the shielding regions 240a, 240b as implanted regions with the bottom shielding regions 240a being formed after the gate trench 180, which may be referred to herein as a post-trench shield implant process. The operations shown in FIGS. 6A to 6H and 12A to 12H may thereby be advantageous with respect to ease of forming the implanted regions 240b with different depths, concentrations, and/or materials than the bottom shielding regions 240a. For example, the use of different implantation processes 600, 605, and 610 may allow for selection of different implantation energies and/or dopant profiles, e.g., to form the support shielding regions 240b to extend to a greater depth and/or with a different dopant concentration than the bottom shielding regions 240a. In some embodiments, the bottom shielding regions 240a may be formed with similar or lower dopant concentration than the support shielding regions 240b. The forming of the bottom shielding regions 240a after formation of the gate trench 180 may also result in a similar (e.g., Gaussian) distribution of dopants over the depths of the shielding regions 240a and 240b (from the bottom surface of the trench 180 towards the substrate 110 and from adjacent the surface S1 towards the substrate 110, respectively).

However, it will be understood that, in other embodiments, the bottom shielding regions 240a may be formed prior to forming the gate trenches 180 (e.g., in the first implantation process of FIG. 6C or the second implantation process of FIG. 6D, with the implanting process 610 of FIG. 6H omitted), which may be referred to herein as a pre-trench shield implant process. Also, while illustrated as being formed of the first dopant material (e.g., Al) in FIG. 6H, the bottom shielding region 240a may alternatively be formed of the second, lighter atomic weight dopant in some embodiments. As a further alternative, the bottom shielding region 240a may be omitted in some embodiments.

Embodiments of the present disclosure may thus utilize a lighter material of a second conductivity type (e.g., having an atomic weight that is less than Al) to provide implanted regions 240b2 in the semiconductor structure 106 to a greater depth D2 but with a similar or same implantation energy as may be used to implant a heavier material of the second conductivity type to provide implanted regions 240b1 to a shallower depth D1. In some embodiments, the implanted regions 240b1 and/or 240b2 may provide the support shielding regions that include first and second dopant materials, where one of the materials is lighter than the other, and/or where at least one of the materials is lighter than Al (e.g., B, Be, Mg).

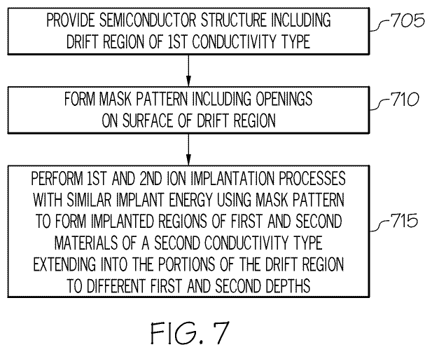

While illustrated in FIGS. 2 to 7 as being implemented in trenched vertical semiconductor power transistors (MOSFET or IGBT), it will be understood that embodiments of the present disclosure are not limited to trenched devices. For example, FIG. 8 is a schematic cross-sectional view illustrating an example unit cell of a planar gate power semiconductor device (illustrated as power MOSFET 800) including support shielding regions of lighter atomic weight materials according to some embodiments of the present disclosure.

As shown in FIG. 8, the power MOSFET 800 includes a semiconductor structure 106 similar to that of FIG. 2, but without the trenches 180. In particular, the power MOSFET 800 includes a substrate 110 and a drift region 120 of a first conductivity type (e.g., n-type) and implanted regions 240b of a second conductivity type (e.g., p-type). The drift region 120 may be wide bandgap semiconductor material (such as SiC), and may include a current spreading layer of the first conductivity type having a higher dopant concentration than the lower portions of the drift region 120. Moderately-doped second conductivity type (e.g., p-type) layers act as the well regions (e.g., “P-wells”) 170, and heavily-doped first conductivity type (e.g., N⁺) regions 160 formed in the well regions 170 provide the source regions 160, with vertical transistor channels or conduction paths 178 (shown by dotted arrows) being formed in the moderately-doped regions P-wells 170. Source contacts 190 on the source regions 160, a drain contact 192 on the lower surface of the substrate 110 on the second side S2, a gate contact (not shown) electrically connected to each gate electrode 184, an intermetal dielectric layer 186 on the gates 184, and a metal layer 196 on the intermetal dielectric layer 186 to contact the source contacts 190 are likewise provided as in the embodiment 200 of FIG. 2.

In contrast to FIG. 2, the planar power MOSFET 800 of FIG. 8 includes the gate insulating layers 282 and gates 284 formed as planar structures extending on the first side or surface S1. Portions of the drift region 120 that are under and/or adjacent the gate electrode 284 provide the “JFET region” 175. The implanted regions 240b (including first portions 240b1 of a heavier atomic weight dopant material and second portion 240b2 of a lighter atomic weight dopant material) extend from the P-wells 170 adjacent the first side S1 of the semiconductor structure 106 towards the second side S2. The fabrication and advantages of the implanted regions 240b may be similar to the embodiments discussed above with reference to FIGS. 2 to 7.

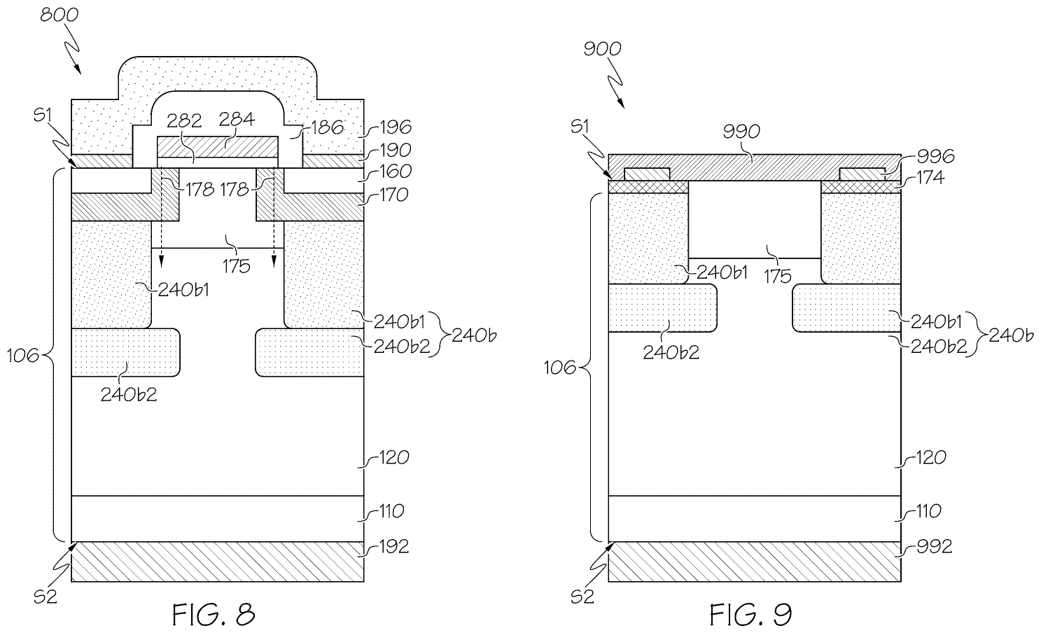

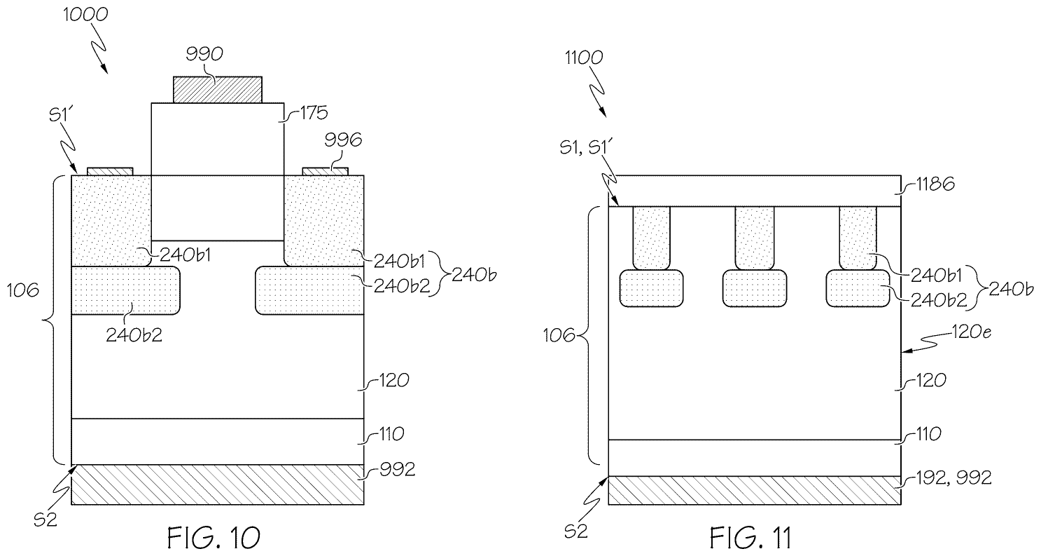

While illustrated in FIGS. 2 to 8 as being implemented as shielding regions 240b in power transistor devices, it will be understood that embodiments of the present disclosure may include other applications, such as trenched or planar Schottky (JBS) diodes, or other power devices requiring an implanted region of the opposite conductivity type than the semiconductor structure. For example, FIG. 9 is a schematic cross-sectional view illustrating an example unit cell of a junction barrier Schottky (JBS) diode including well regions of lighter atomic weight materials according to some embodiments of the present disclosure, while FIG. 10 is a schematic cross-sectional view illustrating an example unit cell of a trench JBS diode including well regions of lighter atomic weight materials according to some embodiments of the present disclosure.

As shown in FIGS. 9 and 10, the JBS diodes 900 and 1000 include a semiconductor structure 106 somewhat similar to that of FIG. 2, with a substrate 110 and a drift region 120 (e.g., a wide bandgap semiconductor material, such as SiC) of a first conductivity type (e.g., n-type) and implanted regions 240b of a second conductivity type (e.g., p-type). In the JBS diodes 900 and 1000, the implanted regions 240b of the second conductivity type provide well regions (e.g., “P+wells”) that create a series of p-n junctions with the surrounding drift region 120 of the first conductivity type, in some embodiments with junction regions 175 in the drift region 120 and/or heavily-doped second conductivity type (e.g., P⁺) regions 174 formed in the wells 240b. The JBS diodes 900, 1000 also include an anode (Schottky) contact 990 on the first side or surface S1, S1′ of the semiconductor structure 106, and a cathode (ohmic) contact 992 on the second or surface side S2 of the semiconductor structure.

The anode contact 990 is a metal layer that forms a Schottky barrier at the metal-semiconductor junction with the drift region 120. Ohmic contacts 996 may also be provided on the heavily-doped regions 174 on the first surface S1 (in the planar JBS diode 900 of FIG. 9) or directly on the implanted regions 240b on the first surface S1′ (which is recessed in the trench JBS diode 1000 of FIG. 10) of the semiconductor structure 106. The implanted regions 240b (including first portions 240b1 of a heavier atomic weight dopant material and second portion 240b2 of a lighter atomic weight dopant material) extend from adjacent the first side S1, S1′ of the semiconductor structures 106 towards the second side S2. The fabrication and advantage of the implanted regions 240b may be similar to the embodiments discussed above with reference to FIGS. 2 to 7.

More generally, embodiments of the present disclosure may be used to form implanted regions of greater depths without increasing implantation energy (and associated lattice damage) in any power semiconductor structure that includes first and second device terminals (e.g., source and drain; anode and cathode) on opposite sides of a drift region, and includes a junction in the drift region that is configured to be biased to conduct electrical current between the first and second device terminals.

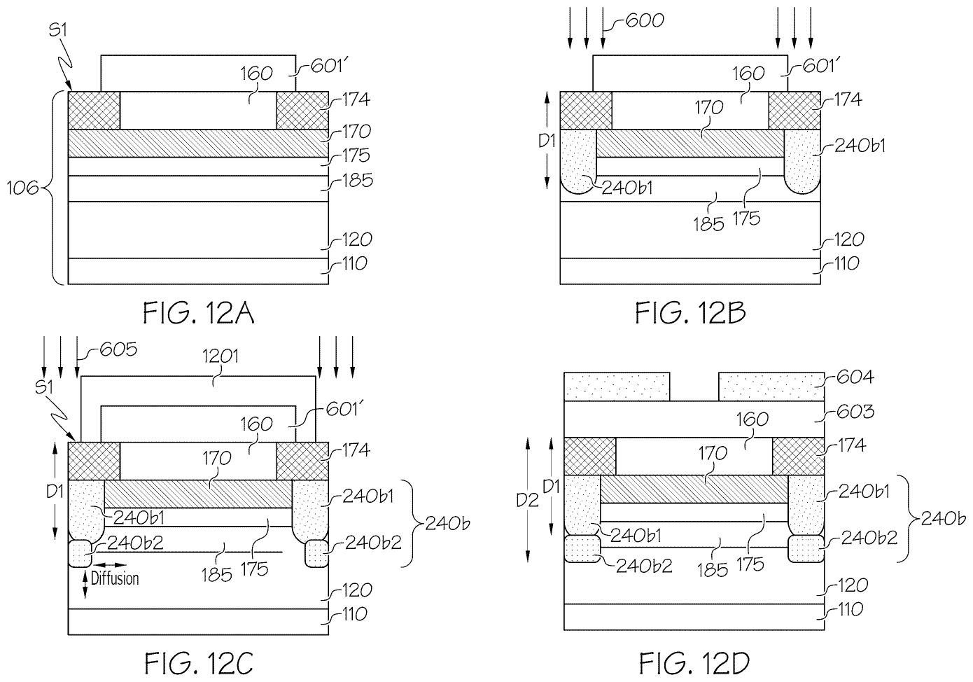

The edge termination of power semiconductor structures described herein may also include deep shielding patterns (e.g., formed by deep ion implantation) to form guard rings that may provide a smooth field transition between the termination and the active region. However, forming such patterns using high energy implantation may result in lateral extension (or “straggle”) between laterally adjacent implant regions, which may electrically connect adjacent implant features. As such termination guard rings may be formed using similar fabrication operations and processes as described herein, embodiments of the present inventive concepts can be similarly applied such that the implanted regions 240b form guard rings in edge termination regions of any of the power semiconductor structures 200, 300, 400a-400b, 500a-500c, 800, 900, 1000 described herein. FIG. 11 is a schematic cross-sectional view illustrating an example edge termination region of a power semiconductor device including termination rings of lighter atomic weight materials according to some embodiments of the present disclosure.

As shown in FIG. 11, the edge termination region 1100 includes a portion of the drift region 120 between the active conduction regions and the peripheral edge 120e of the device structures 200, 300, 400a-400b, 500a-500c, 800, 900, 1000, and may include field oxide and/or passivation layer(s) 1186 on the first surface S1, S1′. The implanted regions 240b (including first portions 240b1 of a heavier atomic weight dopant material and/or second portions 240b2 of a lighter atomic weight dopant material) extend from adjacent the first side S1, S1′ of the semiconductor structure 106 towards the second side S2, and provide termination rings or guard rings 240b in the edge termination region 1100. The fabrication and advantage of the implanted regions 240b may be similar to the embodiments discussed above with reference to FIGS. 2 to 7. Moreover, the operations described herein with respect to limiting lateral diffusion of the portions 240b2 of the implanted regions 240b (e.g., by channeling ion implantation and/or co-implantation with an additional dopant material, such as carbon) may be particularly advantageous to avoid straggle between laterally adjacent guard rings 240b.

In the description above, each example embodiment is described with reference to regions of particular conductivity types. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide bandgap semiconductor material system. As an example, gallium nitride based semiconductor materials (e.g., gallium nitride, aluminum gallium nitride, etc.) may be used instead of silicon carbide in any of the embodiments described above. More generally, while discussed with reference to silicon carbide devices, embodiments of the present invention are not so limited, and may have applicability to devices formed using other wide bandgap semiconductor materials, for example, gallium nitride, zinc selenide, or any other II-VI or III-V wide bandgap compound semiconductor materials.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a fabrication operations. It will be appreciated that the steps shown in the fabrication operations need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A power semiconductor device, comprising:
a semiconductor structure comprising a first side, a second side, and a drift region of a first conductivity type therebetween; and
implanted regions of a second conductivity type in the semiconductor structure adjacent the first side of the semiconductor structure,
wherein the implanted regions comprise a first dopant material and a second dopant material, the second dopant material is between the first dopant material and the second side of the semiconductor structure, and an atomic weight of the second dopant material is lighter than that of the first dopant material.

2. The power semiconductor device of claim 1, wherein the atomic weight of the second dopant material is less than that of aluminum (Al).

3. The power semiconductor device of claim 1, wherein the second dopant material comprises at least one of boron (B), beryllium (Be), or magnesium (Mg).

4. The power semiconductor device of claim 1, further comprising:
a source contact and a gate on the first side of the semiconductor structure, wherein the gate is in or on a portion of the drift region between the implanted regions,
wherein the implanted regions are support shielding regions of a transistor comprising the source contact and the gate.

5. The power semiconductor device of claim 4, further comprising:
a gate trench including the gate therein extending into the portion of the drift region from the first side of the semiconductor structure toward the second side,
wherein the support shielding regions are spaced apart from opposing sidewalls of the gate trench and extend toward the second side beyond a bottom surface of the gate trench.

6. The power semiconductor device of claim 5, further comprising:
a bottom shielding region of the second conductivity type under the bottom surface of the gate trench,
wherein the support shielding regions extend toward the second side beyond the bottom shielding region.

7. The power semiconductor device of claim 6, wherein the bottom shielding region comprises one of the first dopant material or the second dopant material.

8. The power semiconductor device of claim 5, wherein lateral spacings between the support shielding regions are non-uniform over respective depths thereof.

9. The power semiconductor device of claim 1, wherein surfaces of the drift region comprising the implanted regions therein are recessed relative to at least a portion of the drift region therebetween.

10. The power semiconductor device of claim 1, further comprising:
an anode contact on the first side of the semiconductor structure, wherein the anode contact comprises a metal that defines a Schottky barrier with the drift region,
wherein the implanted regions are well regions of a diode comprising the Schottky barrier.

11. The power semiconductor device of claim 1, wherein the drift region comprises an active region and an edge termination region that is between the active region and a peripheral edge of the semiconductor structure, and wherein the implanted regions are termination rings that extend into the edge termination region.

12. The power semiconductor device of claim 1, wherein second portions of the implanted regions comprising the second dopant material laterally extend towards one another beyond first portions of the implanted regions comprising the first dopant material.

13. The power semiconductor device of claim 3, wherein the semiconductor structure comprises a silicon carbide substrate and/or one or more silicon carbide epitaxial layers, and the implanted regions further comprise carbon (C).

14. A power semiconductor device, comprising:
a semiconductor structure comprising a first side, a second side, and a drift region of a first conductivity type therebetween; and
implanted regions comprising a material of a second conductivity type in the semiconductor structure adjacent the first side of the semiconductor structure,
wherein an atomic weight of the material of the second conductivity type is less than that of aluminum (Al).

15. The power semiconductor device of claim 14, wherein the material of the second conductivity type comprises at least one of boron (B), beryllium (Be), or magnesium (Mg).

16. The power semiconductor device of claim 15, wherein lateral spacings between the implanted regions are non-uniform over respective depths thereof.

17. The power semiconductor device of claim 16, wherein the drift region comprises silicon carbide (SiC), and the implanted regions further comprise carbon (C).

18. The power semiconductor device of claim 14, further comprising:
a source contact and a gate on the first side of the semiconductor structure, wherein the gate is in or on a portion of the drift region between the implanted regions,
wherein the implanted regions are support shielding regions of a transistor comprising the source contact and the gate.

19. The power semiconductor device of claim 18, further comprising:
a gate trench including the gate therein extending into the portion of the drift region from the first side of the semiconductor structure toward the second side,
wherein the support shielding regions are spaced apart from opposing sidewalls of the gate trench and extend toward the second side beyond a bottom surface of the gate trench.

20. The power semiconductor device of claim 14, further comprising:
an anode contact on the first side of the semiconductor structure, wherein the anode contact comprises a metal that defines a Schottky barrier with the drift region,
wherein the implanted regions are well regions of a diode comprising the Schottky barrier.

21. The power semiconductor device of claim 14, wherein the drift region comprises an active region and an edge termination region that is between the active region and a peripheral edge of the semiconductor structure, and wherein the implanted regions are termination rings that extend into the edge termination region.

22. A method of fabricating a power semiconductor device, the method comprising:
providing a semiconductor structure comprising a drift region of a first conductivity type;
providing a mask pattern on a surface of the semiconductor structure, the mask pattern including openings therein exposing portions of the semiconductor structure; and
implanting a first dopant material of a second conductivity type in the portions of the semiconductor structure to a first depth relative to the surface thereof,
implanting a second dopant material of the second conductivity type in the portions of the semiconductor structure to a second depth relative to the surface thereof,
wherein implanting the first dopant material and implanting the second dopant material are performed with a substantially similar implant energy to form first and second portions of implanted regions in the semiconductor structure, respectively, and wherein the second depth is greater than the first depth.

23.-36. (canceled)
